(19) United States
(12) Patent Application Publication
(10) Pub. No.: US 2015/0333043 A1
(43) Pub. Date: Nov. 19, 2015

(54) SEMICONDUCTOR DEVICE

(71) Applicant: MITSUBISHI ELECTRIC CORPORATION, Tokyo (JP)

(72) Inventor: Koichi MASUDA, Tokyo (JP)

(73) Assignee: Mitsubishi Electric Corporation, Tokyo (JP)

(21) Appl. No.: 14/640,425

(22) Filed: Mar. 6, 2015

(30) Foreign Application Priority Data
May 19, 2014 (JP) 2014-102998

(51) Int. Cl. H01L 25/07; H05K 1/18; H01L 25/18

(52) U.S. Cl. CPC H01L 25/072; H01L 25/18; H05K 1/181; H05K 2201/10166; H05K 2201/10174; H05K 2201/10522; H05K 2201/1053; H05K 2201/10363

(57) ABSTRACT

A first diode having a front surface anode region is mounted on a P pattern, and a second diode having a front surface cathode region is mounted on an N pattern. At this time, the first diode and the second diode are formed such that a cathode region of a front surface anode region in a first vertical relationship and an anode region of a front surface cathode region in a second vertical relationship are always located as upper portions. The front surface anode region is electrically connected to the front surface cathode region with wires provided thereover.

### BACKGROUND OF THE INVENTION

1. Field of the Invention

The present invention relates to a semiconductor device such as a power module including a built-in circuit including a diode and more particularly to miniaturization of the device.

2. Description of the Background Art

Miniaturization of semiconductor devices has become a challenge, the semiconductor devices such as power modules including converter circuits that electrically connect vertical semiconductor devices in series in the same direction.

In the semiconductor devices, chips such as a diode and a transistor forming semiconductor elements are mounted such that the same electrode surfaces have the same polarity. For example, in a case where a semiconductor device formed of a plurality of diodes is formed, anode electrodes are each disposed on front surfaces of all chips. Thus, in a case where polarities of the chips (semiconductor elements) are connected in series in the same direction, relatively time-consuming wiring through electric wires such as a wire bonding and a metal pattern is required to electrically connect between an electrode formed on a front surface of one chip and an electrode formed on a back surface of the other chip because the chips to be connected have the polarities different from each other.

Conventionally, to resolve the challenge mentioned above, semiconductor modules that laminate a plurality of vertical semiconductor devices (semiconductor elements) in series connection have been developed with the techniques disclosed in Japanese Patent Application Laid-Open No. 2007-27432 and Japanese Patent Application Laid-Open No. 2008-244388.

However, as with the techniques disclosed in Japanese Patent Application Laid-Open No. 2007-27432 and Japanese Patent Application Laid-Open No. 2008-244388, the semiconductor modules that laminate the plurality of vertical semiconductor devices in series connection have problems described below.

First of all, chips (upper side chips) mounted on chips (lower side chips) directly mounted on a supporting plate (substrate) have poor heat dissipation because the upper side chips are not in contact with the supporting plate, namely, the heat dissipating member. Moreover, the lower side chips are mounted to be paths for dissipating heat generated by the upper side chips, so that the lower side chips are also influenced by heat interference. Thus, the first problem is the poor heat dissipation.

In addition, the upper side chips are needed to be smaller than the lower side chips to connect electrodes for obtaining an output current from surfaces connected between the lower side chips and the upper side chips. Thus, the second problem is the unbalanced performances between the upper side chips and the lower side chips.

### SUMMARY OF THE INVENTION

It is an object of the present invention to provide a semiconductor device that has an increasingly reduced size, has high heat dissipation, and has no restriction on a size of a semiconductor element (chip) mounted.

A semiconductor device of the present invention includes a first semiconductor element and a second semiconductor element. The first semiconductor element is mounted on a first circuit pattern and has one first electrode region and the other first electrode region. The second semiconductor element is mounted on a second circuit pattern independently of the first semiconductor element and has one second electrode region and the other second electrode region.

The one first electrode region of the first semiconductor element is electrically connected to the other second electrode region of the second semiconductor element through an intermediate connection point. At least one semiconductor element of the first semiconductor element and the second semiconductor element is a diode. The first and second semiconductor elements are formed such that a first vertical relationship of the one first electrode region with the other first electrode region coincides with a second vertical relationship of the other second electrode region with the one second electrode region.

The semiconductor device of the present invention with the characteristics above can electrically connect between the one first electrode region and the other second electrode region relatively easily that are formed in the common vertical relationship, whereby the area of the circuit in the device can be reduced.

Furthermore, the first and second semiconductor elements are not laminated to prevent the poor heat dissipation, and the first and second semiconductor elements can be provided independently of each other without restricting upon the formation of the first and second semiconductor elements.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A and 1B are explanatory diagrams showing a principle of a semiconductor device of the present invention;

FIGS. 2A and 2B are explanatory diagrams showing a configuration of a power module including a converter circuit according to a first preferred embodiment of the present invention;

FIGS. 3A and 3B are explanatory diagrams showing a configuration of a power module including a converter circuit according to a second preferred embodiment of the present invention;

FIG. 4 is a cross-sectional view showing a sectional structure taken along an A-A line of FIG. 3B;

FIGS. 5A, 5B, and 5C are explanatory diagrams showing a configuration of a power module including a step-down chopper circuit according to a third preferred embodiment of the present invention;

FIGS. 6A, 6B, and 6C are explanatory diagrams showing a configuration of a power module including a step-up chopper circuit according to a fourth preferred embodiment of the present invention;

FIG. 7 is an explanatory diagram showing a specific configuration of a conventional power module for achieving the converter circuit shown in FIG. 1A; and

FIG. 8 is an explanatory diagram showing a specific configuration of a conventional power module for achieving the converter circuit shown in FIG. 2A.

### DESCRIPTION OF THE PREFERRED EMBODIMENTS

### Principle of Invention

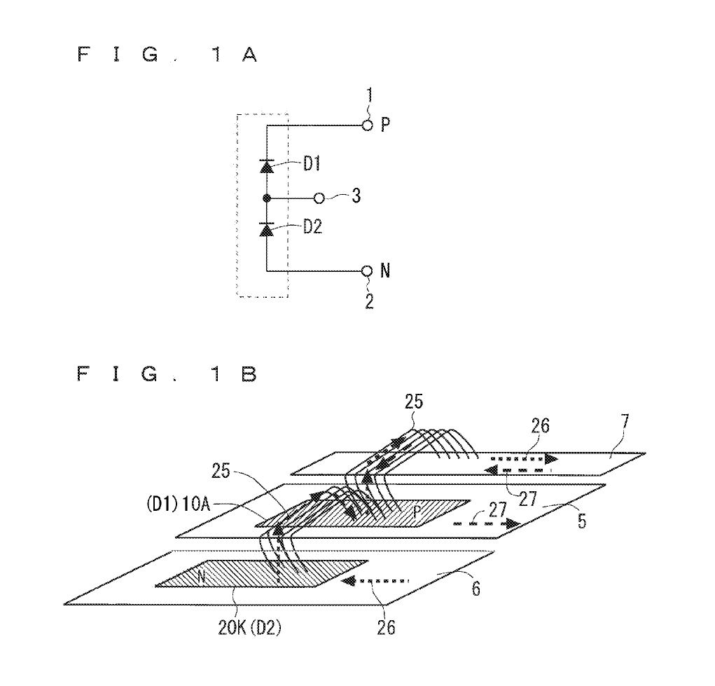

FIG. 1 is an explanatory diagram showing a principle of a power module being a semiconductor device of the present invention. As shown in FIG. 1A, a converter circuit is formed of a combination (portion defined by a dashed line) of a diode D1 and a diode D2 (first semiconductor element and second semiconductor element) connected in series. The diode D1 (first diode) includes an anode (one first electrode region) and a cathode (the other first electrode region). The diode D2 (second diode) has an anode (one second electrode region) and a cathode (the other second electrode region). Specifically, the cathode of the diode D1 is connected to a P terminal 1, the anode of the diode D1 is electrically connected to the cathode of the diode D2, and the anode of the diode D2 is connected to an N terminal 2. An intermediate terminal 3 is provided at an intermediate connection point between the anode of the diode D1 and the cathode of the D2.

FIG. 1B shows a specific configuration for achieving the converter circuit shown in FIG. 1A. As shown in FIG. 1B, a P pattern 5 (first circuit pattern), an N pattern 6 (second circuit pattern), and an intermediate pattern 7 are provided as the circuit patterns for the converter circuit. The P pattern 5, the N pattern 6, and the intermediate pattern 7 are formed independently of one another on a substrate (supporting plate), which is not shown, for example.

The diode D1 (chip for the diode D1) having a front surface anode region 10A as an upper portion is mounted on the P pattern 5. The diode D2 (chip for the diode D2) having a front surface cathode region 20K as an upper portion is mounted on the N pattern 6.

Wires 25 (conductive members) provided over the front surface anode region 10A and the front surface cathode region 20K electrically connect therebetween. The plurality of wires 25 are used for supplying a large current. The wires 25 provided over the front surface anode region 10A and the intermediate pattern 7 electrically connect therebetween. This configuration can provide a current path 26 (27) from the N pattern 6 (N terminal 2) to the P pattern 5 (P terminal 1) through the diode D2 and the diode D1 (and the intermediate pattern 7 (intermediate terminal 3)).

FIG. 7 is an explanatory diagram showing a specific configuration of a conventional power module for achieving the converter circuit shown in FIG. 1A.

As shown in FIG. 7, a P pattern 55, an N pattern 56A, an N pattern 56B, and an intermediate pattern 57 are provided as the circuit patterns for a comparator circuit. The diode D1 (chip for the diode D1) having a front surface anode region 60A as an upper portion is mounted on the P pattern 55. The diode D2 (chip for the diode D2) having a front surface anode region 70A as an upper portion is mounted on the N pattern 56A.

A back surface cathode region 70BK (not shown) located below the front surface anode region 70A is electrically connected to the front surface anode region 60A in the following manner. A connection pattern 56CP electrically connected to the back surface cathode region 70BK is provided in the front surface of the N pattern 56A, and the wires 25 provided over the connection pattern 56CP and the front surface anode region 70A electrically connect therebetween. In addition, FIG. 7 only shows the connection pattern 56CP schematically, so that it does not necessarily coincide with the actual shape.

Moreover, the wires 25 provided over the front surface anode region 60A and the intermediate pattern 57 electrically connect therebetween, and wires 25X provided over the front surface anode region 70A and the N pattern 56B electrically connect therebetween.

This configuration can provide the current path 26 (27) from the N patterns 56A and 56B (N terminal 2) to the P pattern 55 (P terminal 1) through the diode D2 and the diode D1 (and the intermediate pattern 57 (intermediate terminal 3)).

As described with reference to FIGS. 1A and 1B, in the power module of the present invention, the combination of the diode chips used for the converter circuit is formed of the combination of the diode D1 (chip for the diode D1) having the front surface anode (back surface cathode) and the diode D2 (chip for the diode D2) having the back surface anode (front surface cathode).

In other words, two types of diodes D1 and D2 in which the anode is disposed above the cathode in one vertical relationship and the cathode is disposed above the anode in the other vertical relationship are used, allowing for reductions in the number of circuit patterns and the area thereof and for flexibility in a design of the pattern.

As seen from the comparison between FIGS. 1A, 1B and FIG. 7, the principle of the present invention requires the three circuit patterns (P pattern 5, N pattern 6, intermediate pattern 7) while the conventional configuration requires the four circuit patterns (P pattern 55, N pattern 56A, N pattern 56B, intermediate pattern 57).

The conventional configuration provides the connection pattern 56CP in the N pattern 56A for electrically connecting between the back surface cathode region 70BK and the front surface anode region 60A and also requires the wires 25X to electrically connect between the front surface anode region 70A and the N pattern 56B. In contrast, the principle of the present invention eliminates the need for the connection pattern 56CP and the wires 25X described above, whereby the area of the circuit and the place for metal wiring such as wires can be reduced. Thus, the present invention can have effects of reducing the area of the circuit and reducing the place for the metal wiring to shorten the time for assembly.

Alternatively, in this specification, the example of connecting with the wires 25 is shown as an example of the metal wiring being the conductive member, and the metal bonding such as a direct lead bonding (DLB) may be used.

In this manner, the power module shown by the principle of the present invention is characterized to form the diode D1 and the diode D2 such that the cathode region of the front surface anode region 10A of the diode D1 in one vertical relationship and the anode region of the front surface cathode region 20K of the diode D2 in the other vertical relationship are always located as the upper portions, the front surface anode region 10A and the front surface cathode region 20K requiring the electrical connection therebetween. In other words, the first vertical relationship of the front surface anode region 10A with the cathode region coincides with the second vertical relationship of the front surface cathode region 20K with the anode region.

The present invention with the characteristics above can electrically connect between the front surface anode region 10A and the front surface cathode region 20K relatively easily that are formed in the common vertical relationship, whereby the area of the circuit in the device can be reduced.

Furthermore, the diode D1 and the diode D2 are not laminated to prevent the poor heat dissipation, and the chips for the diode D1 and the diode D2 can be provided independently of each other without restricting the sizes of the chips to prevent the unbalanced performances between the diodes D1 and D2. As a result, safety of the product can be increased.

Consequently, the power module can reduce the area of the circuit to function as the converter circuit that is formed of the diode D1 and the diode D2, passes a current from the intermediate terminal 3 to the P terminal 1, receives, for example, an alternating-current input signal from the intermediate terminal 3, and obtains a direct-current output signal from the P terminal 1 (cathode of the diode D1) with reference to the N terminal 2 (anode of the diode D2).

### First Preferred Embodiment

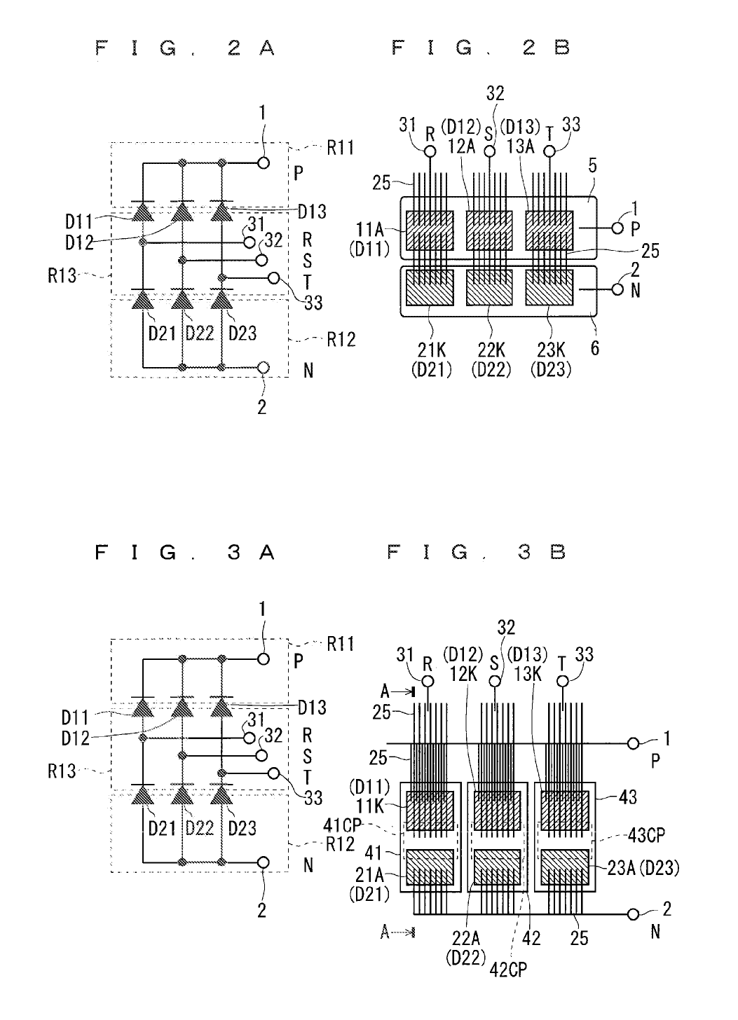

FIGS. 2A and 2B are explanatory diagrams showing a configuration of a power module including a converter circuit according to a first preferred embodiment of the present invention. Hereinafter, only the minimum number of circuit patterns required is shown because a product may have a configuration that wires directly connect chips (semiconductor elements) to an electrode portion in some cases.

As shown in FIG. 2A, the converter circuit is formed of diodes D11 to D13 (first semiconductor elements) and diodes D21 to D23 (second semiconductor elements). The diodes D11 to D13 (a plurality of first diodes) include anodes (one first electrode regions) and cathodes (the other first electrode regions). The diodes D21 to 23 (a plurality of second diodes) include anodes (one second electrode region) and cathodes (the other second electrode regions). Specifically, each of the cathodes of the diodes D11 to D13 is connected in common to a P terminal 1, the anodes of the diodes D11 to D13 are electrically connected to the cathodes of the diodes D21 to D23, and each of the anodes of the diodes D21 to D23 is connected in common to an N terminal 2. Intermediate terminals 31 to 33 are provided at each of intermediate connection points between the anodes of the diodes D11 to D13 and the cathodes of the diodes D21 to D23. The intermediate terminals 31 to 33 input an alternating-current signal of an R phase, an S phase, and a T phase.

In this manner, the converter circuit forming a full bridge (three-phase full-wave rectifying circuit) is formed of a P terminal area R11, an N terminal area R12, and an intermediate terminal area R13. The P terminal area R11 includes the P terminal 1 and the diodes D11 to D13 as main structural components. The N terminal area R12 includes the N terminal 2 and the diodes D21 to D23 as main structural components. The intermediate terminal area R13 includes (anode portions of) the diodes D11 to D13, (cathode portions of) the diodes D21 to D23, and the intermediate terminals 31 to 33 as main structural components.

FIG. 2B shows a specific configuration for achieving the converter circuit shown in FIG. 2A. In other words, a P pattern 5 and an N pattern 6 are provided as circuit patterns for the converter circuit. Circuit patterns for the intermediate terminals 31 to 33 can be replaced with wires or the like, so that only the intermediate terminals 31 to 33 without the circuit patterns are simply shown.

The diodes D11 to D13 (chips for the diodes D11 to D13) having front surface anode regions 11A to 13A as upper portions are mounted on the P pattern 5. The diodes D21 to D23 (chips for the diodes D21 to D23) having front surface cathode regions 21K to 23K as upper portions are mounted on the N pattern 6 provided independently of the P pattern 5.

The wires 25 (conductive members) provided over the front surface anode regions 11A to 13A and the front surface cathode regions 21K to 23K electrically connect therebetween, respectively. The wires 25 provided over the front surface anode regions 11A to 13A and the intermediate terminals 31 to 33 electrically connect therebetween. This configuration can provide a current path from the N pattern 6 (N terminal 2) to the P pattern 5 (P terminal 1) through the diodes D21 to D23 and the diodes D11 to D13 (and the intermediate terminals 31 to 33).

FIG. 8 is an explanatory diagram showing a specific configuration of a conventional power module for achieving the converter circuit shown in FIG. 2A.

As shown in FIG. 8, a P pattern 55 and N patterns 561 to 563 are provided as circuit patterns for the converter circuit. Circuit patterns for the N terminal 2 and the intermediate terminals 31 to 33 can be replaced with wires or the like, so that the N terminal 2 and the intermediate terminals 31 to 33 without the circuit patterns are only shown. The diodes D11 to D13 (chips for the diodes D11 to D13) having front surface anode regions 61A to 63A as upper portions are mounted on the P pattern 55, and the diodes D21 to D23 (chips for the diodes D21 to D23) having front surface anode regions 71A to 73A as upper portions are mounted on the N patterns 561 to 563.

Then, back surface cathode regions 71BK to 73BK (not shown) located below the front surface anode regions 71A to 73A are electrically connected to the front surface anode regions 61A to 63A in the following manner. Connection patterns 561CP to 563CP electrically connected to the back surface cathode regions 71BK to 73BK are provided in front surfaces of the N patterns 561 to 563, and the wires 25 provided over the connection patterns 561CP to 563CP and the front surface anode regions 71A to 73A electrically connect therebetween. In addition, FIG. 8 only shows the connection patterns 561CP to 563CP schematically, so that they do not necessarily coincide with the actual shapes.

Moreover, the wires 25 provided over the front surface anode regions 61A to 63A and the intermediate terminals 31 to 33 electrically connect therebetween, and the wires 25X provided over the front surface anode regions 71A to 73A and the N terminal 2 electrically connect therebetween.

This configuration can provide the conventional power module with a current path from the N terminal 2 to the P pattern 55 (P terminal 1) through the diodes D21 to D23 and the diodes D11 to D13 (and the intermediate terminals 31 to 33).

As shown in FIG. 8, in a case where the conventional power module forms the full-bridge converter circuit, wires, a lead bonding (means of connecting an inner lead to a bump with a bonding tool), or the like cannot directly connect between the front surface anode regions 61A to 63A of the diodes D11 to D13 on the P terminal 1 side and the back surface cathode regions 71BK to 73BK of the diodes D21 to D23 on the N terminal 2 side.

As a result, the excess connection patterns 561CP to 563CP are needed to be provided as described above, thereby increasing the area of the circuit patterns required to form the converter circuit.

On the other hand, in the power module of the first preferred embodiment, the combination of the diode chips used for the converter circuit is formed of the combination of the diodes D11 to D13 (chips for the diodes D11 to D13) having the front surface anodes (back surface cathodes) and the diodes D21 to D23 (chips for the diodes D21 to D23) having the back surface anodes (front surface cathodes).

Moreover, the wires 25 provided over the front surface anode regions 11A to 13A in the P pattern 5 on the P terminal 1 side and the front surface cathode regions 21K to 23K in the N pattern 6 on the N terminal 2 side can directly connect therebetween, so that the area of the circuit patterns and the wires or the lead bonding can be reduced compared to the conventional structure shown in FIG. 8.

In other words, two types of (chips for) diodes D11 to D13 and diodes D21 to D23 in which the anodes are disposed above the cathodes in one vertical relationships and the cathodes are disposed above the anodes in the other vertical relationships are used, allowing for reductions in the number of circuit patterns and the area thereof and for flexibility in a design of the pattern.

As seen from the comparison between FIG. 2B and FIG. 8, the first preferred embodiment requires the two circuit patterns (P pattern 5, N pattern 6) at minimum while the conventional configuration requires the four circuit patterns (P pattern 55, N patterns 561 to 563) at minimum.

In this manner, the power module of the first preferred embodiment reduces the number of circuit patterns required, eliminating the need for the area of a clearance required to maintain the insulating state between the circuit patterns, thereby achieving the effect of reducing the area of the entire device.

The conventional configuration provides the connection patterns 561CP to 563CP in the front surfaces of the N patterns 561 to 563 for electrically connecting between the back surface cathode regions 71BK to 73BK and the front surface anode regions 61A to 63A and also requires the wires 25X to electrically connect between the front surface anode regions 71A to 73A and the N terminal 2.

In contrast, the power module of the first preferred embodiment eliminates the need for the connection patterns 561CP to 563CP and the wires 25X described above, whereby the areas of the circuit patterns and the place for the metal wiring can be reduced. Thus, the power module can have the effects of reducing the area of the circuit and reducing the place for the metal wiring to shorten the time for assembly.

In this manner, the power module of the first preferred embodiment is characterized to form the diodes D11 to D13 and the diodes D21 to D23 such that the cathode regions of the front surface anode regions 11A to 13A in the first vertical relationship and the anode regions of the front surface cathode regions 21K to 23K in the second vertical relationship are always located as the upper portions, the front surface anode regions 11A to 13A requiring the electrical connection.

The power module of the first preferred embodiment with the characteristics above can electrically connect between the front surface anode regions 11A to 13A and the front surface cathode regions 21K to 23K relatively easily that are formed in the common vertical relationship, whereby the area of the circuit in the device can be reduced.

Specifically, the wires 25 (conductive members) provided above the front surface anode region 22A and the front surface cathode regions 21K to 23K electrically connect therebetween, whereby the area of the circuit can be reduced.

Furthermore, the diodes D11 to D13 and the diodes D21 to D23 are not laminated to prevent the poor heat dissipation and the restriction on the sizes of the chips forming the diodes D11 to D13 and the diodes D21 to D23 provided independently of each other.

Moreover, the power module of the first preferred embodiment can be obtained by mounting the diodes D11 to D13 on the common P pattern 5 (first circuit pattern) and mounting the diodes D21 to D23 on the common N pattern 6 (second circuit pattern), and thus the number of circuit patterns required can be reduced.

As a result, upon the formation of the converter circuit for the alternating-current input signal of the three phases input from the intermediate terminals 31 to 33, the number of circuit patterns required can be suppressed to a minimum to simplify the circuit configuration.

In this manner, the power module of the first preferred embodiment can reduce the area of the circuit to function as the converter circuit that is formed of the diodes D11 to D13 and the diodes D21 to D23, passes a current from the intermediate terminals 31 to 33 to the P terminal 1, receives, for example, the alternating-current input signal of the three phases from the intermediate terminals 31 to 33, and obtains the direct-current output signal from the P terminal 1 (cathodes of the diodes D11 to D13) with reference to the N terminal 2 (anodes of the diodes D21 to D23).

### Second Preferred Embodiment

FIGS. 3A and 3B are explanatory diagrams showing a configuration of a power module including a converter circuit according to a second preferred embodiment of the present invention. Hereinafter, only the minimum number of circuit patterns required is shown because a product may have a configuration that wires directly connect chips to an electrode portion in some cases.

As shown in FIG. 3A, the converter circuit is formed of the diodes D11 to D13 and the diodes D21 to D23 similarly to the first preferred embodiment.

FIG. 3B shows a specific configuration for achieving the converter circuit shown in FIG. 3A. In other words, common patterns 41 to 43 (common circuit patterns (first and second circuit patterns)) are provided as circuit patterns for the converter circuit. The common patterns 41 to 43 are formed independently of one another on a substrate, which is not shown, for example. The circuit patterns for the P terminal 1, the N terminal 2, and the intermediate terminals 31 to 33 can be replaced with wires or the like, so that the P terminal 1, the N terminal 2, and the intermediate terminals 31 to 33 without the circuit patterns are only shown.

The diode D11 (chip for the diode D11) having a front surface cathode region 11K as an upper portion is mounted on the common pattern 41 while the diode D21 (chip for the diode D21) having a front surface anode region 21A as an upper portion is mounted independently of the diode D11. Similarly, the diode D12 (chip for the diode D12) having a front surface cathode region 12K as an upper portion is mounted on the common pattern 42 while the diode D22 (chip for the diode D22) having a front surface anode region 22A as an upper portion is mounted independently of the diode D12, and the diode D13 (chip for the diode D13) having a front surface cathode region 13K as an upper portion is mounted on the common pattern 43 while the diode D23 (chip for the diode D23) having a front surface anode region 23A as an upper portion is mounted independently of the diode D13.

The wires 25 (conductive members) provided over the front surface cathode regions 11K to 13K and the P terminal 1 electrically connect therebetween, and the wires 25 provided over the front surface anode regions 21A to 23A and the N terminal 2 electrically connect therebetween. Furthermore, the back surface anode regions 11BA to 13BA (not shown) are located below the front surface cathode regions 11K to 13K, and connection patterns (not shown) are provided between the back surface anode regions 11BA to 13BA of the diodes D11 to D13 and the intermediate terminals 31 to 33 in the front surfaces of the common patterns 41 to 43. The back surface anode regions 11BA to 13BA are electrically connected to the intermediate terminals 31 to 33 with the wires 25 provided thereover and the connection patterns electrically connected to the back surface anode regions 11BA to 13BA.

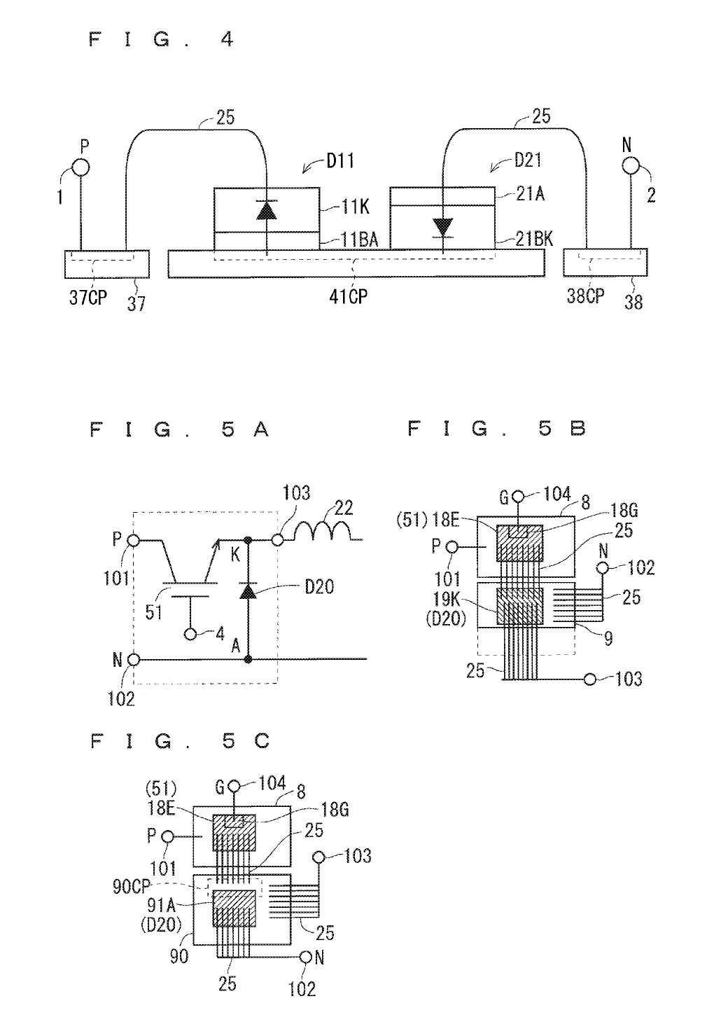

FIG. 4 is a cross-sectional view showing a cross-sectional structure taken along an A-A line of FIG. 3B. FIG. 4 shows the case where the P terminal 1 is provided on a P pattern 37 and the N terminal 2 is provided on an N pattern 38.

As shown in FIG. 4, the diodes D11 and D21 (chips for the diodes D11 and D21) are mounted on the common pattern 41, the diode D11 is formed in the first vertical relationship having the front surface cathode region 11K as an upper portion and the back surface anode region 11BA as a lower portion, and the diode D21 is formed in the second vertical relationship having the front surface anode region 21A as an upper portion and a back surface cathode region 21BK as a lower portion.

The front surface cathode region 11K of the diode D11 is electrically connected to the P terminal 1 through the wires 25 and a connection pattern 37CP provided in the front surface of the P pattern 37. Meanwhile, the front surface anode region 21A of the diode D21 is electrically connected to the N terminal 2 through the wires 25 and a connection pattern 38CP provided in the front surface of the N pattern 38.

The back surface anode region 11BA of the diode D11 is electrically connected to the back surface cathode region 21BK of the diode D21 through only a connection pattern 41CP (electrical connection portion) provided in the front surface of the common pattern 41. Similarly, the back surface anode region 12BA (not shown) of the diode D12 is electrically connected to the back surface cathode region 22BK (not shown) of the diode D22 through only a connection pattern 42CP (electrical connection portion) provided in the front surface of the common pattern 42, and the back surface anode region 13BA (not shown) of the diode D13 is electrically connected to the back surface cathode region 23BK (not shown) of the diode D23 through only a connection pattern 43CP (electrical connection portion) provided in the front surface of the common pattern 43. In addition, FIG. 3B and FIG. 4 only show the connection patterns 41CP to 43CP, 37CP, and 38CP schematically, so that they do not necessarily coincide with the actual shapes.

In this manner, the front surface cathode regions 11K to 13K of the diodes D11 to D13 are electrically connected to the front surface anode regions 21A to 23A of the diodes D21 to D23 through the three connection patterns 41CP to 43CP provided in the front surfaces of the common patterns 41 to 43.

The example of the connection with the P pattern 37 and the N pattern 38 shown in FIG. 4 is given for illustration. The P terminal 1 and the N terminal 2 may be directly connected to the front surface cathode region 11K and the front surface anode region 21A with wires or the like. Moreover, the connection patterns 41CP to 43CP may function as connection patterns for electrically connecting between the back surface anode regions 11BA to 13BA and the intermediate terminals 31 to 33.

The power module of the second preferred embodiment having the above-mentioned configuration can provide a current path from the N terminal 2 to the P terminal 1 through the diodes D21 to D23 and the diodes D11 to D13 (and the intermediate terminals 31 to 33).

In the power module of the second preferred embodiment, the combination of the diode chips used for the converter circuit is formed of the combination of the diodes D11 to D13 (chips for the diodes D11 to D13) having the back surface anodes (front surface cathodes) and the diodes D21 to D23 (chips for the diodes D21 to D23) having the front surface anodes (back surface cathodes).

Only the connection patterns 41CP to 43CP in the front surfaces of the common patterns 41 to 43 can electrically connect between the back surface anode regions 11BA to 13BA and the back surface cathode regions 21BK to 23BK that are provided in the common patterns 41 to 43, so that the reduction in the number of circuit patterns compared to the conventional structure shown in FIG. 8 can reduce the area of the circuit patterns and the wires or the lead bonding.

In other words, two types (first and second vertical relationships) of diodes D11 to D13 and D21 to D23 in which the anodes are disposed above the cathodes in one vertical relationships and the cathodes are disposed above the anodes in the other vertical relationships are used, allowing for the reductions in the number of patterns and the area and for flexibility in a design of the pattern.

As seen from the comparison between FIG. 3 and FIG. 8, the second preferred embodiment requires the three circuit patterns (common patterns 41 to 43) while the conventional configuration requires the four circuit patterns (P pattern 55, N patterns 561 to 563).

In this manner, the power module of the second preferred embodiment reduces the number of circuit patterns required, eliminating the need for the area of a clearance required to maintain the insulating state between the circuit patterns, thereby achieving the effect of reducing the area of the entire device.

The conventional configuration provides the connection patterns 561CP to 563CP in the front surfaces of the N patterns 561 to 563 for electrically connecting between the back surface cathode regions 71BK to 73BK and the front surface anode regions 61A to 63A and also requires the wires 25X to electrically connect between the front surface anode regions 71A to 73A and the N terminal 2. In the second preferred embodiment, only the connection patterns 41CP to 43CP can perform the electrical connection, whereby the areas of the circuit patterns and the place for the metal wiring such as wires can be reduced. Thus, the second preferred embodiment can have the effects of reducing the area of the circuit and reducing the place for the metal wiring to shorten the time for assembly.

As described above, the power module of the second preferred embodiment is characterized to form the diodes D11 to D13 and the diodes D21 to D23 such that the back surface anode regions 11BA to 13BA below the front surface cathode regions 11K to 13K in the first vertical relationship and the back surface cathode regions 21BK to 23BK below the front surface anode regions 21A to 23A in the second vertical relationship are always located as the lower portions, the back surface anode regions 11BA to 13BA requiring the electrical connection.

The power module of the second preferred embodiment with the characteristics above can electrically connect between the back surface anode regions 11BA to 13BA and the back surface cathode regions 21BK to 23BK relatively easily that are formed in the common vertical relationship, whereby the area of the circuit in the device can be reduced.

Specifically, in the second preferred embodiment, the connection patterns 41CP to 43CP (electrical connection portions) provided in the front surfaces of the common patterns 41 to 43 electrically connect between the back surface anode regions 11BA to 13BA and the back surface cathode regions 21BK to 23BK, whereby the area of the circuit can be reduced.

Furthermore, the second preferred embodiment similar to the first preferred embodiment can reduce the area of the circuit of the power module without causing the poor heat dissipation and restricting the sizes of the chips for the diodes D11 to D13 and the diodes D21 to D23, the power module functioning as the converter circuit that receives a three-phase alternating-current signal.

Moreover, in the second preferred embodiment, the diodes D11 to D13 and the diodes D21 to D23 in pairs on the P terminal 1 side and the N terminal 2 side can be formed on the common patterns 41 to 43, respectively. As a result, in the second preferred embodiment, upon the formation of the converter circuit for the alternating-current input signal of the three phases input from the intermediate terminals 31 to 33, the circuit patterns required can be suppressed to a minimum to simplify the circuit configuration.

### Third Preferred Embodiment

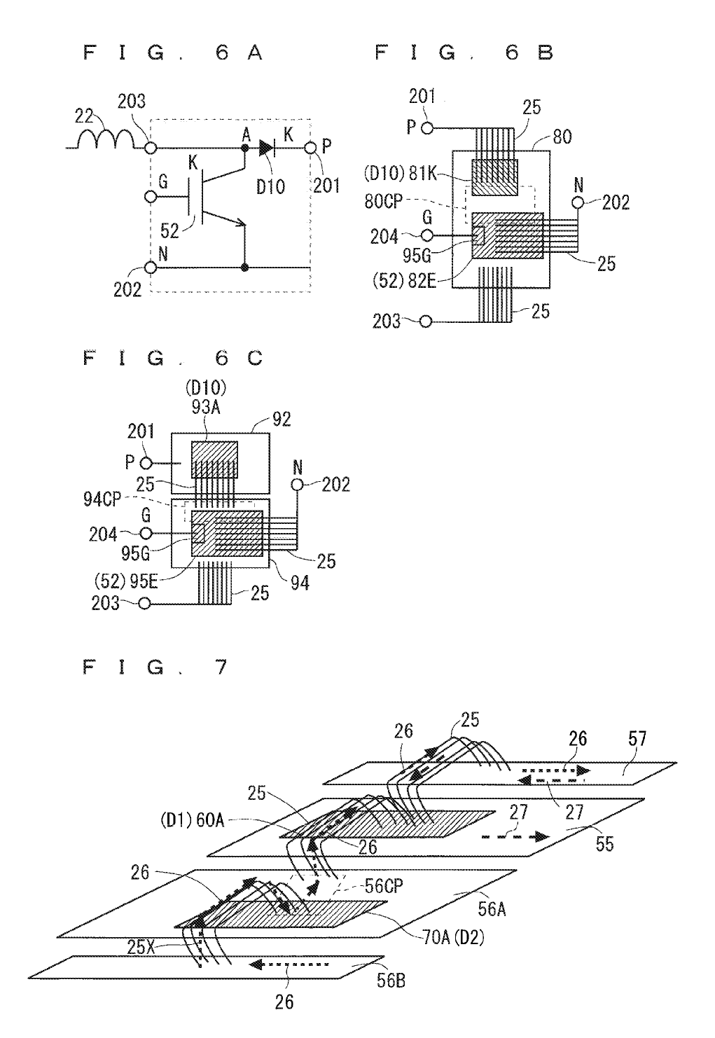

FIGS. 5A, 5B, and 5C are explanatory diagrams showing a configuration of a power module including a step-down chopper circuit according to a third preferred embodiment of the present invention. Hereinafter, only the minimum number of circuit patterns required is shown because a product may have a configuration that wires directly connect chips to an electrode portion in some cases.

As shown in FIG. 5A, the step-down chopper circuit in the power module of the third preferred embodiment is formed of a combination (module portion defined by a dashed line) of an N-type IGBT 51 (first semiconductor element) and a diode D20 (second semiconductor element) as the main portion. The IGBT 51 includes an emitter (one first electrode region) and a collector (the other first electrode region). The diode D20 includes an anode (one second electrode region) and a cathode (the other second electrode region). Specifically, the collector of the IGBT 51 is connected to a P terminal 101, the emitter of the IGBT 51 is electrically connected to the cathode of the diode D20, and the anode of the diode D20 is connected to an N terminal 102. An intermediate terminal 103 is provided at an intermediate connection point between the emitter of the IGBT 51 and the cathode of the diode D20. A reactor 22 is connected to the intermediate terminal 103.

FIG. 5B shows a specific configuration for achieving the step-down chopper circuit shown in FIG. 5A. In other words, a transistor pattern 8 (first circuit pattern) and a diode pattern 9 (second circuit pattern) are provided as circuit patterns for the step-down chopper circuit. The transistor pattern 8 and the diode pattern 9 are formed independently of each other on a substrate, which is not shown, for example. Circuit patterns for the N terminal 102 and the intermediate terminal 103 can be replaced with wires or the like, so that only the N terminal 102 and the intermediate terminal 103 without the circuit patterns are simply shown.

The IGBT 51 (chip for the IGBT 51) having an N-type front surface emitter region 18E as an upper portion is mounted on the transistor pattern 8, and the diode D20 (chip for the diode 20) having a front surface cathode region 19K as an upper portion is mounted on the diode pattern 9.

The wires 25 (conductive members) provided over the front surface emitter region 18E and the front surface cathode region 19K electrically connect therebetween. The wires 25 provided over the front surface cathode region 19K and the intermediate terminal 103 electrically connect therebetween. A back surface anode region 19BA (not shown) located below the front surface cathode region 19K is provided in the front surface of the diode pattern 9. The back surface anode region 19BA is electrically connected to the N terminal 2 through a connection pattern (not shown) and the wires 25 that are electrically connected to the back surface anode region 19BA. A front surface gate region 18G is electrically connected to a gate terminal 104.

With this configuration, the power module of the third preferred embodiment functions as the step-down chopper circuit that passes a current from the P terminal 101 to the intermediate terminal 103, obtains an input signal from, for example, the P terminal 101 (collector of the IGBT 51), sets a reference potential at the N terminal 102 (anode of the diode D20), and obtains an output signal from the intermediate terminal 103.

FIG. 5C is an explanatory diagram showing a specific configuration of a conventional power module for achieving the step-down chopper circuit shown in FIG. 5A.

As shown in FIG. 5C, the transistor pattern 8 and a diode pattern 90 are provided as circuit patterns for the step-down chopper circuit, the IGBT 51 (chip for the IGBT 51) having the front surface emitter region 18E as an upper portion is mounted on the transistor pattern 8, and the diode D20 (chip for the diode D20) having the front surface anode region 91A as an upper portion is mounted on the diode pattern 90.

A back surface cathode region 91BK (not shown) located below the front surface anode region 91A is electrically connected to the front surface emitter region 18 in the following manner. A connection pattern 90CP electrically connected to the back surface cathode region 91BK is provided in the front surface of the diode pattern 90. The back surface cathode region 91BK is electrically connected to the front surface emitter region 18E with the wires 25 provided over a portion between the connection pattern 90CP and the front surface emitter region 18E. In addition, FIG. 5C only shows the connection pattern 90CP schematically, so that it does not necessarily coincide with the actual shape.

Furthermore, the wires 25 provided over the front surface anode region 91A and the N terminal 102 electrically connect therebetween, the back surface cathode region 91BK (not shown) located below the front surface anode region 91A is provided in the front surface of the diode pattern 90, and the back surface cathode region 91BK is electrically connected to the intermediate terminal 103 through a connection pattern (not shown) and the wires 25 that are electrically connected to the back surface cathode region 91BK. The front surface gate region 18G is electrically connected to the gate terminal 104.

As shown in FIG. 5C, in a case where the step-down chopper circuit is formed in the conventional power module, wires, a lead bonding, or the like cannot directly connect between the front surface emitter region 18E of the IGBT 51 on the P terminal 101 side and the back surface cathode region 91BK of the diode D20 on the N terminal 102 side. Thus, the back surface of the chip (back surface cathode region 91BK of the diode D20) on the N terminal 102 side is connected to the front surface of the chip (front surface emitter region 18E of the IGBT 51) on the P terminal 101 side through the connection pattern 90CP that is electrically connected to the back surface cathode region 91BK, thereby increasing the pattern area of the diode pattern 90 required to form the step-down chopper circuit.

On the other hand, the power module of the third preferred embodiment is formed of the combination of the IGBT 51 (chip for the IGBT 51) and the diode D20 (chip for the diode D20) of the back surface anode (front surface cathode) upon mounting of the step-down chopper circuit.

Moreover, the wires 25 provided over the front surface emitter region 18E in the transistor pattern 8 on the P terminal 101 side and the front surface cathode region 19K in the diode pattern 9 on the N terminal 102 side can directly connect therebetween, so that the area of the patterns and the wires or the lead bonding can be reduced compared to the conventional structure shown in FIG. 5C.

In other words, as seen from the comparison between FIG. 5B and FIG. 5C, the conventional configuration provides the connection pattern 90CP in the diode pattern 90 for electrically connecting between the back surface cathode region 91BK and the front surface emitter region 18E and also requires the wires 25 to electrically connect between the front surface anode region 91A and the N terminal 102. In contrast, the third preferred embodiment eliminates the need for the connection pattern 90CP described above, whereby the area of the circuit can be reduced.

In this manner, the power module of the third preferred embodiment can omit a connection pattern corresponding to the connection pattern 90CP, so that the area of the diode pattern 9 can be reduced more than that of the diode pattern 90, allowing for flexibility in a design of the pattern. As a result, the time for assembly can be shortened.

As described above, the power module of the third preferred embodiment is characterized to form the IGBT 51 and the diode D20 such that the collector region of the front surface emitter region 18E in the first vertical relationship and the anode region of the front surface cathode region 19K in the second vertical relationship are always located as the upper portions, the front surface emitter region 18E requiring the electrical connection.

The power module of the third preferred embodiment with the characteristics above can electrically connect between the front surface emitter region 18E and the front surface cathode region 19K relatively easily that are formed in the common vertical relationship, whereby the area of the circuit in the device can be reduced.

Specifically, the wires 25 (conductive members) provided over the front surface emitter region 18E and the front surface cathode region 19K electrically connect therebetween, whereby the area of the circuit can be reduced.

As a result, the area of the circuit of the power module formed of the IGBT 51 and the diode D20 and functioning as the step-down chopper circuit can be reduced.

Furthermore, the IGBT 51 and the diode D20 are not laminated to prevent the poor heat dissipation and the restriction on the sizes of the chips for the IGBT 51 and the diode D20.

In the third preferred embodiment, the IGBT 51 is shown as the switching element, and the other switching elements such as a MOSFET and a bipolar transistor may be used.

### Fourth Preferred Embodiment

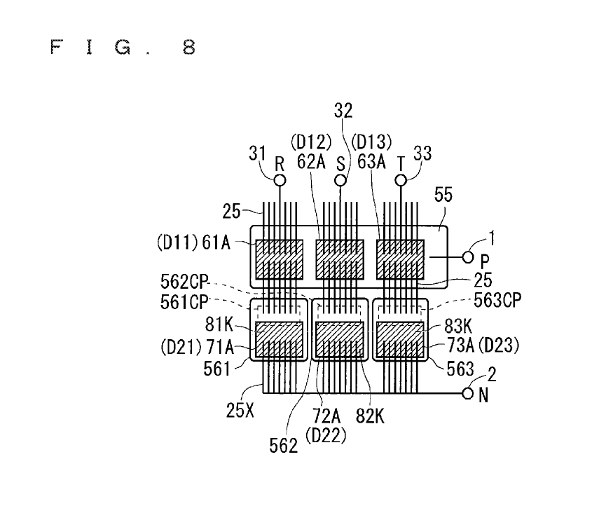

FIGS. 6A, 6B, and 6C are explanatory diagrams showing a configuration of a power module including a step-up chopper circuit according to a fourth preferred embodiment of the present invention. Hereinafter, only the minimum number of circuit patterns required is shown because a product may have a configuration that wires directly connect chips to an electrode portion in some cases.

As shown in FIG. 6A, the step-up chopper circuit in the power module of the fourth preferred embodiment is formed of a combination (portion defined by a dashed line) of a diode D10 (first semiconductor element) and an N-type IGBT 52 (second semiconductor element) as the main portion. The diode D10 includes an anode (one first electrode region) and a cathode (the other first electrode region). The IGBT 52 includes an emitter (one second electrode region) and a collector (the other second electrode region). Specifically, the cathode of the diode D10 is connected to a P terminal 201, the anode of the diode D10 is electrically connected to the collector of the IGBT 52, and the emitter of the IGBT 52 is connected to an N terminal 202. An intermediate terminal 203 is provided at an intermediate connection point between the anode of the diode D10 and the collector of the IGBT 52. A reactor 22 is connected to the intermediate terminal 203.

FIG. 6B shows a specific configuration for achieving the step-up chopper circuit shown in FIG. 6A. In other words, a common pattern 80 (common circuit pattern (first and second circuit patterns)) is provided as a circuit pattern for the step-up chopper circuit. The common pattern 80 is formed on a substrate, which is not shown, for example. Circuit patterns for the P terminal 201, N terminal 202, and the intermediate terminal 203 can be replaced with wires or the like, so that only the P terminal 201, the N terminal 202, and the intermediate terminal 203 without the circuit patterns are simply shown.

The diode D10 (chip for the diode D10) having the front surface cathode region 81K as an upper portion is mounted on the common pattern 80, and the IGBT 52 (chip for the IGBT 52) having an N-type front surface emitter region 82E as an upper portion is also mounted on the common pattern 80 independently of the diode D10.

A front surface cathode region 81K is electrically connected to the P terminal 201 with the wires 25 provided over the front surface cathode region 81K. The front surface emitter region 82E is electrically connected to the N terminal 202 with the wires 25 provided over the front surface emitter region 82E. A back surface collector region 82BC (not shown) located below the front surface emitter region 82E is electrically connected to the intermediate terminal 203 through the wires 25 and a connection pattern (not shown) provided in the front surface of the common pattern 80.

Furthermore, a back surface anode region 81BA (not shown) located below the front surface cathode region 81K of the diode D10 is electrically connected to the P-type back surface collector region 82BC (not shown) located below the front surface emitter region 82E of the IGBT 52 through only a connection pattern 80CP provided in the front surface of the common pattern 80. The connection pattern 80CP may function as a connection pattern for electrically connecting between the back surface collector region 82BC and the intermediate terminal 203. In addition, FIG. 6B only shows the connection pattern 80CP schematically, so that it does not necessarily coincide with the actual shape.

With this configuration, the power module of the fourth preferred embodiment function as the step-up chopper circuit that passes a current from the intermediate terminal 203 to the P terminal 201, sets a reference potential at, for example, the N terminal 202 (emitter of the IGBT 52), obtains an input signal from the intermediate terminal 203 (collector of the IGBT 52, anode of the diode D10), and obtains an output signal from the P terminal 201 (cathode of the diode D10).

FIG. 6C is an explanatory diagrams showing a specific configuration of a conventional power module for achieving the step-up chopper circuit shown in FIG. 6A.

As shown in FIG. 6C, a diode pattern 92 and a transistor pattern 94 are provided as circuit patterns for the step-up chopper circuit, the diode D10 (chip for the diode D10) having a front surface anode region 93A as an upper portion is mounted on the diode pattern 92, and the IGBT 52 (chip for the IGBT 52) having a front surface emitter region 95E as an upper portion is mounted on the transistor pattern 94.

A back surface collector region 95BC (not shown) located below the front surface emitter region 95E is electrically connected to the front surface anode region 93A in the following manner. A connection pattern 94CP electrically connected to the back surface collector region 95BC is provided in the front surface of the transistor pattern 94, and the wires 25 provided over the connection pattern 94CP and the front surface emitter region 95E electrically connect therebetween. In addition, FIG. 6C only shows the connection pattern 94CP schematically, so that it does not necessarily coincide with the actual shape.

Furthermore, the wires 25 provided over the front surface emitter region 95E and the N terminal 202 electrically connect therebetween, and the back surface collector region 95BC located below the front surface emitter region 95E is electrically connected to the intermediate terminal 203 through the wires 25 and a connection pattern (not shown) provided in the transistor pattern 94. A front surface gate region 95G is electrically connected to a gate terminal 204.

As shown in FIG. 6C, in a case where the step-up chopper circuit is formed in the conventional power module, wires, a lead bonding, or the like cannot directly connect between the front surface anode region 93A of the diode D10 on the P terminal 201 side and the back surface collector region 95BC of the IGBT 52 on the N terminal 202 side. Thus, the back surface of the chip (back surface collector region 95BC of the IGBT 52) on the N terminal 202 side is electrically connected to the connection pattern 94CP, and in addition to that, the back surface of the chip is connected to the front surface of the chip (front surface anode region 93A of the diode D10) on the P terminal 201 side through the wires 25 provided thereover. Moreover, the two circuit patterns that are the diode pattern 92 and the transistor pattern 94 are required.

Meanwhile, the power module of the fourth preferred embodiment is formed of the combination of the IGBT 52 and the diode D10 of the back surface anode (front surface cathode) upon mounting of the step-up chopper circuit.

On the same common pattern 80, the back surface anode region 81BA on the P terminal 201 side can be directly connected to the back surface collector region 82BC on the N terminal 202 side through only the connection pattern 80CP in the front surface of the common pattern 80, whereby the number of circuit patterns can be reduced compared to the conventional structure shown in FIG. 6C. In other words, the diode D10 of the back surface anode and the IGBT 52 are used, allowing for the reduction in the number of patterns and for flexibility in a design of the pattern.

As seen from the comparison between FIG. 6B and FIG. 6C, the fourth preferred embodiment requires the one circuit pattern (common pattern 80) at minimum while the conventional configuration requires the two circuit patterns (diode pattern 92, transistor pattern 94).

In this manner, the power module of the fourth preferred embodiment reduces the number of circuit patterns required, eliminating the need for the area of a clearance required to maintain the insulating state between the circuit patterns, thereby achieving the effect of reducing the area of the entire device.

As described above, the power module of the fourth preferred embodiment is characterized to form the diode D10 and the IGBT 52 such that the back surface anode region 81BA below the front surface cathode region 81K in the first vertical relationship and the back surface collector region 82BC below the front surface emitter region 82E in the second vertical relationship are always located as the lower portions, the back surface anode region 81BA requiring the electrical connection.

The power module of the fourth preferred embodiment with the characteristics above can electrically connect between the back surface anode region 81BA and the back surface collector region 82BC relatively easily that are formed in the common vertical relationship, whereby the area of the circuit in the device can be reduced.

Specifically, only the connection pattern 80CP (electrical connection portion) provided in the front surface of the common pattern 80 electrically connects between the back surface anode region 81BA and the back surface collector region 82BC, whereby the area of the circuit can be reduced.

As a result, the power module of the fourth preferred embodiment is formed of the diode D10 and the IGBT 52 and can reduce the area of the circuit of the power module functioning as the step-up chopper circuit.

Furthermore, the diode D10 and the IGBT 52 are not laminated to prevent the poor heat dissipation and the restriction on the sizes of the chips for the diode D10 and the IGBT 52.

In the fourth preferred embodiment, the IGBT 52 is shown as the switching element, and the other switching elements such as a MOSFET and a bipolar transistor may be used.

### Fifth Preferred Embodiment

The chips (semiconductor elements) of the diode and the IGBT as shown in the first to fourth preferred embodiments are not limited to silicon (Si) as the constituent material, and semiconductor elements made of a wide band gap (semiconductor) material, such as silicon carbide (SiC) and gallium nitride (GaN), may be used.

In other words, the wide band gap material used in high temperature operation and a high current region is used for the semiconductor elements (diodes D10 to D13, diodes D20 to D23, and the IGBTs 51 and 52) in the power module of the first to fourth preferred embodiments, to thereby improve the effects of reducing the external size of the device with the high heat dissipation of this structure, as compared to the Si.

In addition, according to the present invention, the above preferred embodiments can be arbitrarily combined, or each preferred embodiment can be appropriately varied or omitted within the scope of the invention.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
a first semiconductor element that is mounted on a first circuit pattern and has one first electrode region and the other first electrode region; and
a second semiconductor element that is mounted on a second circuit pattern independently of said first semiconductor element and has one second electrode region and the other second electrode region, wherein
said one first electrode region of said first semiconductor element is electrically connected to said other second electrode region of said second semiconductor element through an intermediate connection point,
at least one semiconductor element of said first semiconductor element and said second semiconductor element is a diode, and
said first and second semiconductor elements are formed such that a first vertical relationship of said one first electrode region with said other first electrode region coincides with a second vertical relationship of said other second electrode region with said one second electrode region.

2. The semiconductor device according to claim 1, wherein
said first semiconductor element and said second semiconductor element are a first diode and a second diode, respectively,
said one first electrode region and said one second electrode region are anode regions and said other first electrode region and said other second electrode region are cathode regions, and
a current passes from said intermediate connection point to said other first electrode region.

3. The semiconductor device according to claim 2, wherein
said first circuit pattern and said second circuit pattern are provided independently of each other, and
said first and second vertical relationships include a vertical relationship in which said one first electrode region and said other second electrode region are respectively disposed above said other first electrode region and said one second electrode region, said one first electrode region being electrically connected to said other second electrode region with a conductive member provided thereover.

4. The semiconductor device according to claim 2, wherein
said first and second circuit patterns include the same common circuit pattern, and
said first and second vertical relationships include a vertical relationship in which said one first electrode region and said other second electrode region are respectively disposed below said other first electrode region and said one second electrode region, said one first electrode region being electrically connected to said other second electrode region through an electrical connection portion provided in a surface of said common circuit pattern.

5. The semiconductor device according to claim 3, wherein
said first diode includes a plurality of first diodes,
said second diode includes a plurality of second diodes provided correspondingly to said plurality of first diodes, and
said intermediate connection point includes a plurality of intermediate connection points provided correspondingly to said plurality of first diodes and second diodes.

6. The semiconductor device according to claim 4, wherein
said first diode includes a plurality of first diodes,
said second diode includes a plurality of second diodes provided correspondingly to said plurality of first diodes, and
said intermediate connection point includes a plurality of intermediate connection points provided correspondingly to said plurality of first diodes and second diodes.

7. The semiconductor device according to claim 1, wherein
said first semiconductor element is a switching element and said second semiconductor element is a diode,
said one second electrode region is an anode region and said other second electrode region is a cathode region,
a current passes from said other first electrode region to said intermediate connection point,
said first circuit pattern and said second circuit pattern are provided independently of each other, and
said first and second vertical relationships include a vertical relationship in which said one first electrode region and said other second electrode region are respectively disposed above said other first electrode region and said one second electrode region, said one first electrode region being electrically connected to said other second electrode region with a conductive member provided thereover.

8. The semiconductor device according to claim 1, wherein
said first semiconductor element is a diode and said second semiconductor element is a switching element,
said one first electrode region is an anode region and said other first electrode region is a cathode region,
a current passes from said intermediate connection point to said other first electrode region,
said first and second circuit patterns include the same common circuit pattern, and
said first and second vertical relationships include a vertical relationship in which said one first electrode region and said other second electrode region are respectively disposed below said other first electrode region and said one second electrode region, said one first electrode region being electrically connected to said other second electrode region through an electrical connection portion provided in a surface of said common circuit pattern.

9. The semiconductor device according to claim 1, wherein
said first and second semiconductor elements are formed of a wide band gap material.
